(19) United States
(12) Patent Application Publication
(10) Pub. No.: US 2017/0249996 A1
(43) Pub. Date: Aug. 31, 2017

(54) OPPORTUNISTIC MEMORY TUNING FOR DYNAMIC WORKLOADS

(71) Applicant: Microsoft Technology Licensing, LLC, Redmond, WA (US)

(72) Inventors: Mark W. Gottscho, Los Angeles, CA (US); Mohammed Shoaib, Redmond, WA (US); Sriram Govindan, Redmond, WA (US); Mark Santaniello, Redmond, WA (US); Bikash Sharma, Bellevue, WA (US); J. Michael Andrewartha, Woodinville, WA (US); Jie Liu, Medina, WA (US); Badriddine Khessib, Redmond, WA (US)

(21) Appl. No.: 15/055,466

(22) Filed: Feb. 26, 2016

(51) Int. Cl. G11C 29/38; G11C 29/44

(52) U.S. Cl. CPC G11C 29/38; G11C 29/44

(57) ABSTRACT

Technology relating to tuning for operating memory devices is disclosed. The technology includes a computing device that selectively configures operating parameters for at least one operating memory device based at least in part of performance characteristics for an application or other workload that the computing device has been requested to execute. This technology may be implemented, at least in part, in the firmware via a Basic Input/Output System (BIOS) or Unified Extensible Firmware Interface (UEFI) of the computing device. Further, this technology may be employed by a computing device that is executing workloads on behalf of a distributed computing system, e.g., in a data center. Such data centers may include, for example, thousands of computing devices and even more operating memory devices.

### BACKGROUND

Operating memory devices (e.g., random access memories, dynamic memories, static memories, caches, buffers, etc.) are often employed by computing devices for storing run-time data, executable instructions, and other information. Such memory devices may operate with various parameters, and these parameters may affect the performance characteristics of the operating memory device, the computing device, or of applications executing on the computing device.

Also, various applications may have different responses to different operating memory performance characteristics. For example, some applications may be particularly sensitive to memory latency while other applications may be relatively insensitive to latency, but may benefit from higher bandwidth. However, in conventional technology, the parameters for operating memory devices typically depends on the hardware configuration of the computing device, and are configured prior to or during manufacturing or deployment of a computing device. The parameters for conventional computing devices typically are not changed after a computing device is deployed.

### BRIEF DESCRIPTION OF THE DRAWINGS

Non-limiting and non-exhaustive embodiments of the present invention are described with reference to the following drawings. In the drawings, like reference numerals refer to like parts throughout the various figures unless otherwise specified. These drawings are not necessarily drawn to scale.

For a better understanding of the present invention, reference will be made to the following Detailed Description, which is to be read in association with the accompanying drawings, wherein:

FIG. 1 is a diagram illustrating one example of a suitable environment in which aspects of the technology may be employed;

FIG. 2 is a diagram illustrating one example of a suitable computing device according to aspects of the disclosed technology;

FIG. 3 illustrates an overview of an example embodiment of the disclosed technology;

FIGS. 4A and 4B illustrate performance to configuration relationships according to an example embodiment of the disclosed technology;

FIG. 5 is a logical flow diagram illustrating a process for improving execution performance for a workload according to aspects of the technology; and

FIG. 6 is a logical flow diagram illustrating a process of executing workloads in a distributed computing system according to aspects of the technology.

### DETAILED DESCRIPTION

The following description provides specific details for a thorough understanding of, and enabling description for, various embodiments of the technology. One skilled in the art will understand that the technology may be practiced without many of these details. In some instances, well-known structures and functions have not been shown or described in detail to avoid unnecessarily obscuring the description of embodiments of the technology. It is intended that the terminology used in this disclosure be interpreted in its broadest reasonable manner, even though it is being used in conjunction with a detailed description of certain embodiments of the technology. Although certain terms may be emphasized below, any terminology intended to be interpreted in any restricted manner will be overtly and specifically defined as such in this Detailed Description section. For example, each of the terms “based on” and “based upon” is not exclusive, and is equivalent to the term “based, at least in part, on”, and includes the option of being based on additional factors, some of which may not be described herein. As another example, the term “via” is not exclusive, and is equivalent to the term “via, at least in part”, and includes the option of being via additional factors, some of which may not be described herein. Use of a particular textual numeric designators does not imply the existence of lesser-valued numerical designators. For example, reciting “a widget selected from the group consisting of a third foo and a fourth bar” would not itself imply that there are at least three foo, nor that there are at least four bar, elements. References in the singular are made merely for clarity of reading and include plural references unless plural references are specifically excluded. The term “or” is an inclusive “or” operator unless specifically indicated otherwise. For example, the phrases “A or B” means “A, B, or A and B.” As used herein, the terms “component” and “system” are intended to encompass hardware, software, or various combinations of hardware and software. Thus, for example, a system or component may be a process, a process executing on a computing device, the computing device, or a portion thereof.

### Introduction

Technology relating to tuning for operating memory devices is disclosed. The technology includes a computing device that selectively configures operating parameters for at least one operating memory device based at least in part of performance characteristics for an application or other workload that the computing device has been requested to execute. This technology may be implemented, at least in part, in a firmware of the computing device, such as a Unified Extensible Firmware Interface (UEFI) or a Basic Input/Output System (BIOS) of the computing device. Further, this technology may be employed by a computing device that is executing workloads on behalf of a distributed computing system, e.g., in a data center. Such data centers may include, for example, thousands of computing devices and even more operating memory devices.

In such computing systems, applications and other workloads typically have not been assigned to particular computing devices based on specific or actual performance of those computing devices. Rather, workloads might have been, at best, assigned based on gross generalizations of the computing devices' performance. For example, a workload might perhaps have been assigned to a particular computing device based on processor speed, bus speed, or amount of operating memory installed in that computing device. However, some workloads might have particular sensitivity to memory performance, e.g., memory latency or memory bandwidth. In addition, certain system operators may have an interest in the amount of power consumed by their computing system, including the amount of power consumed by their operating memory devices.

Various computing devices may also include various types of operating memory devices. For example, such computing devices may include dual in-line memory modules (DIMMs), small outline DIMMs (SODIMMs), single in-line memory modules (SIMMs)), operating memory circuits, operating memory cores, operating memory dies, and other operating memory devices from various manufactures and having various performance specifications.

Process and other variations for operating memory devices, for example fabrication variations, packaging variations, temperature variations, and other manufacturing, environmental, or other variations, may mean that the operating memory in a particular computing device may be capable of performing outside of at least one manufacturer specification. For example, a memory device may be able to perform outside a manufacturer specified parameter(s). Such parameters include, but are not limited to:
clock frequency,
bus frequency,
refresh rate,
column access strobe (CAS) cycle latency,
CAS latency time,
row address strobe (RAS) to CAS cycle latency,
RAS to CAS latency time,
RAS precharge cycle latency,
RAS precharge delay time,
row active delay time,
command rate,
column to column delay latency,
column to column delay time, and
data burst duration.
   Accordingly, typical workloads might not be employing the full performance available from the computing device's operating memory.

Further, additional factors may further decrease the efficiency of these and other computer systems. For example, the effect of operating parameters or operating characteristics for a computing device's operating memory might not be a factor in assigning workloads to computing devices, or in configuring computing devices to perform workloads, e.g., because these effects are not known to the computer system or system operator. Accordingly, typical computing systems might not be provisioned to take advantage of the full amount of available computing power.

The presently disclosed technology may be employed, for example, to improve the efficiency or utilization of computing systems and devices, and to improve the performance of workloads. One aspect of the disclosed technology includes characterizing workloads, e.g., to determine the effect of various memory performance characteristics on the workloads. For example, workloads may be analyzed to determine the effects of operating memory latency, random-access speed, burst access speed, or other characteristics on workload performance. The technology may include testing workloads on many computing devices to obtain benchmarked results for each of many operating memory characteristics.

Another aspect of the present disclosed technology includes tuning computing devices to obtain increased performance from operating memory devices. For example, operating memory parameters may be configured, e.g., in BIOS, to test or tune the operating memory performance of a computing device. As an example, operating memory parameters such as clock frequency, bus frequency, refresh rate, CAS timing, RAS timing, RAS to CAS timing, RAS precharge timing, RAS precharge delay timing, row active delay timing, command rate, column to column delay timing, data burst duration, non-uniform memory access (NUMA) settings, rank interleaving, bank interleaving, channel interleaving, or other settings or combinations thereof may be configured and tested for workload performance. These and other settings, and combinations thereof, may also be tested for operating memory reliability.

Another aspect of the presently disclosed technology includes assigning workloads to computing device that have operating memory characteristics that are well-suited to those workloads. For example, workloads that benefit more from lower random access latency than lower burst access speed may be assigned to computing devices with matching operating memory characteristics. Likewise, workloads that benefit more from higher write speed than read speed may be assigned to computing devices with operating memory devices that provide such performance. In addition, workloads that are relatively insensitive to operating memory performance may be assigned to computing devices with operating memories tuned for reduced energy consumption.

In other words, the presently disclosed technology includes characterizing the effect of various operating memory performance characteristics on workloads, and characterizing the effects of various configuration parameters on operating memory performance. The determined effects of the operating memory performance characteristics and operating memory parameters may then be employed to assign workloads to computing devices, and to tune the computing devices to enhance the performance of such workloads. By employing the disclosed technology to map workloads to computing devices an operator of a computing system may improve performance without purchasing more expensive operating memory devices.

### Illustrative Devices/Operating Environments

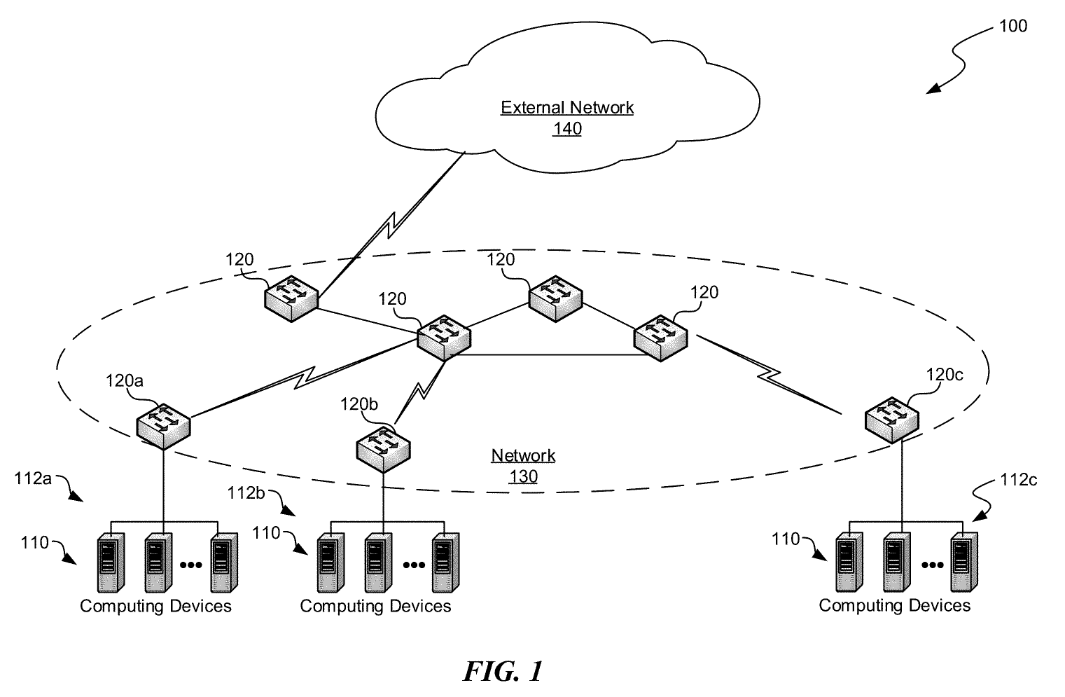

FIG. 1 is a diagram of environment 100 in which aspects of the technology may be practiced. As shown, environment 100 includes computing devices 110, as well as network nodes 120, connected via network 130. Even though particular components of environment 100 are shown in FIG. 1, in other embodiments, environment 100 can also include additional and/or different components. For example, in certain embodiments, the environment 100 can also include network storage devices, maintenance managers, and/or other suitable components (not shown).

As shown in FIG. 1, network 130 can include one or more network nodes 120 that interconnect multiple computing devices 110, and connect computing devices 110 to external network 140, e.g., the Internet or an intranet. For example, network nodes 120 may include switches, routers, hubs, network controllers, or other network elements. In certain embodiments, computing devices 110 can be organized into racks, action zones, groups, sets, or other suitable divisions. For example, in the illustrated embodiment, computing devices 110 are grouped into three host sets identified individually as first, second, and third host sets 112a-112c. In the illustrated embodiment, each of host sets 112a-112c is operatively coupled to a corresponding network node 120a-120c, respectively, which are commonly referred to as “top-of-rack” or “TOR” network nodes. TOR network nodes 120a-120c can then be operatively coupled to additional network nodes 120 to form a computer network in a hierarchical, flat, mesh, or other suitable types of topology that allows communication between computing devices 110 and external network 140. In other embodiments, multiple host sets 112a-112c may share a single network node 120.

Computing devices 110 may be virtually any type of general- or specific-purpose computing device. For example, these computing devices may be user devices such as desktop computers, laptop computers, tablet computers, display devices, cameras, printers, or smartphones. However, in a data center environment, these computing devices may be server devices such as application server computers, virtual computing host computers, or file server computers. Moreover, computing devices 110 may be individually configured to provide computing, storage, and/or other suitable computing services. For example, computing devices 110 can be configured to execute workloads and other processes, such as the workloads and other processes described herein.

### Illustrative Computing Device

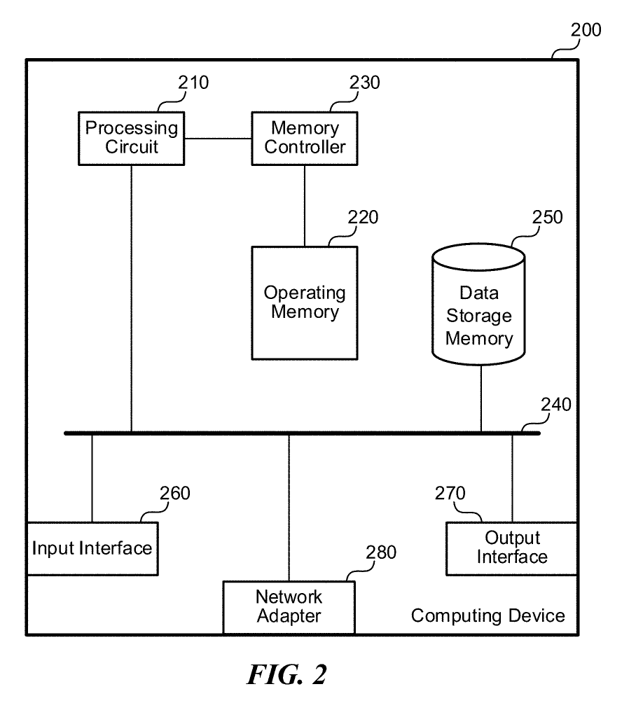

FIG. 2 is a diagram illustrating one example of computing device 200 in which aspects of the technology may be practiced. Computing device 200 may be virtually any type of general- or specific-purpose computing device. For example, computing device 200 may be a user device such as a desktop computer, a laptop computer, a tablet computer, a display device, a camera, a printer, or a smartphone. Likewise, computing device 200 may also be server device such as an application server computer, a virtual computing host computer, or a file server computer, e.g., computing device 200 may be an embodiment of computing device 110 of FIG. 1. As illustrated in FIG. 2, computing device 200 includes processing circuit 210, operating memory 220, memory controller 230, data storage memory 250, input interface 260, output interface 270, and network adapter 280. Each of these afore-listed components of computing device 200 includes at least one hardware element.

Computing device 200 includes at least one processing circuit 210 configured to execute instructions, such as instructions for implementing the herein-described workloads, processes, or technology. Processing circuit 210 may include a microprocessor, a microcontroller, a graphics processor, a coprocessor, a field programmable gate array, a programmable logic device, a signal processor, or any other circuit suitable for processing data. The aforementioned instructions, along with other data (e.g., datasets, metadata, operating system instructions, etc.), may be stored in operating memory 220 during run-time of computing device 200. Operating memory 220 may also include any of a variety of data storage devices/components, such as volatile memories, semi-volatile memories, random access memories, static memories, caches, buffers, or other media used to store run-time information. In one example, operating memory 220 does not retain information when computing device 200 is powered off. Rather, computing device 200 may be configured to transfer instructions from a non-volatile data storage component (e.g., data storage component 250) to operating memory 220 as part of a booting or other loading process.

Operating memory 220 may include 4^{th} generation double data rate (DDR4) memory, 3^{rd} generation double data rate (DDR3) memory, other dynamic random access memory (DRAM), High Bandwidth Memory (HBM), Hybrid Memory Cube memory, 3D stacked memory, static random access memory (SRAM), or other memory, and such memory may comprise one or more memory circuits integrated onto a DIMM, SIMM, SODIMM, or other packaging. Such operating memory modules or devices may be organized according to channels, ranks, and banks. For example, operating memory devices may be coupled to processing circuit 210 via memory controller 230 in channels. One example of computing device 200 may include one or two DIMMs per channel, with one or two ranks per channel. Operating memory within a rank may operate with a shared clock, and shared address and command bus. Also, an operating memory device may be organized into several banks where a bank can be thought of as an array addressed by row and column. Based on such an organization of operating memory, physical addresses within the operating memory may be referred to by a tuple of channel, rank, bank, row, and column.

Despite the above-discussion, operating memory 220 specifically does not include or encompass communications media, any communications medium, or any signals per se.

Memory controller 230 is configured to interface processing circuit 210 to operating memory 220. For example, memory controller 230 may be configured to interface commands, addresses, and data between operating memory 220 and processing circuit 210. Memory controller 230 may also be configured to abstract or otherwise manage certain aspects of memory management from or for processing circuit 210. For example, memory controller 230 may manage refreshing of memory cells, manage memory timing, translate logical memory addresses to physical memory address, or the like, on behalf of processing circuit 210 or computing device 200.

In interfacing operating memory 220 to processing circuit 210, memory controller 230 may also manage various parameters for operating memory. For example, memory controller 230 may manage operating memory parameters such as clock frequency, bus frequency, refresh rate, CAS timing, RAS timing, RAS to CAS timing, RAS precharge timing, RAS precharge delay timing, row active delay timing, command rate, column to column delay timing, data burst duration, NUMA settings, rank interleaving, bank interleaving, channel interleaving, or other settings or combinations thereof. In addition, memory controller 230 may also manage reads and/or writes for processing circuit 210, manage access patterns for processing circuit 210 or operating memory 220, or the like, for example by setting configuration parameters controlling a clock cycle by clock cycle input/output specification or pipeline organization for the operating memory.

Although memory controller 230 is illustrated as single memory controller separate from processing circuit 210, in other example, multiple memory controllers may be employed, memory controller(s) may be integrated with operating memory 220, or the like. Further, memory controller(s) may be integrated into processing circuit 210. These and other variations are possible.

In computing device 200, data storage memory 250, input interface 260, output interface 270, and network adapter 280 are interfaced to processing circuit 210 by bus 240. Although, FIG. 2 illustrates bus 240 as a single passive bus, other configurations, such as a collection of buses, a collection of point to point links, an input/output controller, a bridge, other interface circuitry, or any collection thereof may also be suitably employed for interfacing data storage memory 250, input interface 260, output interface 270, or network adapter 280 to processing circuit 210.

In computing device 200, data storage memory 250 is employed for long-term non-volatile data storage. Data storage memory 250 may include any of a variety of non-volatile data storage devices/components, such as non-volatile memories, disks, disk drives, hard drives, solid-state drives, or any other media that can be used for the non-volatile storage of information. However, data storage memory 250 specifically does not include or encompass communications media, any communications medium, or any signals per se. In contrast to operating memory 220, data storage memory 250 is employed by computing device 200 for non-volatile long-term data storage, instead of for run-time data storage.

Also, computing device 200 may include or be coupled to any type of computer-readable media such as computer-readable storage media (e.g., operating memory 220 and data storage memory 250) and communication media (e.g., communication signals and radio waves). While the term computer-readable storage media includes operating memory 220 and data storage memory 250, this term specifically excludes and does not encompass communications media, any communications medium, or any signals per se.

Computing device 200 also includes input interface 260, which may be configured to enable computing device 200 to receive input from users or from other devices. In addition, computing device 200 includes output interface 270, which may be configured to provide output from computing device 200. In one example, output interface 270 includes a frame buffer, graphics processor, graphics processor or accelerator, and is configured to render displays for presentation on a separate visual display device (e.g., a monitor, projector, virtual computing client computer, etc.). In another example, output interface 270 includes a visual display device and is configured to render and present displays for viewing.

In the illustrated example, computing device 200 is configured to communicate with other computing devices or entities via network adapter 280. Network adapter 280 may include a wired network adapter, e.g., an Ethernet adapter, a Token Ring adapter, or a Digital Subscriber Line (DSL) adapter. Network adapter 280 may also include a wireless network adapter, for example, a Wi-Fi adapter, a Bluetooth adapter, a ZigBee adapter, a Long Term Evolution (LTE) adapter, or a 5G adapter.

Although computing device 200 is illustrated with certain components configured in a particular arrangement, these components and arrangement are merely one example of a computing device in which the technology may be employed. In other examples, data storage memory 250, input interface 260, output interface 270, or network adapter 280 may be directly coupled to processing circuit 210, or be coupled to processing circuit 210 via an input/output controller, a bridge, or other interface circuitry. Other variations of the technology are possible.

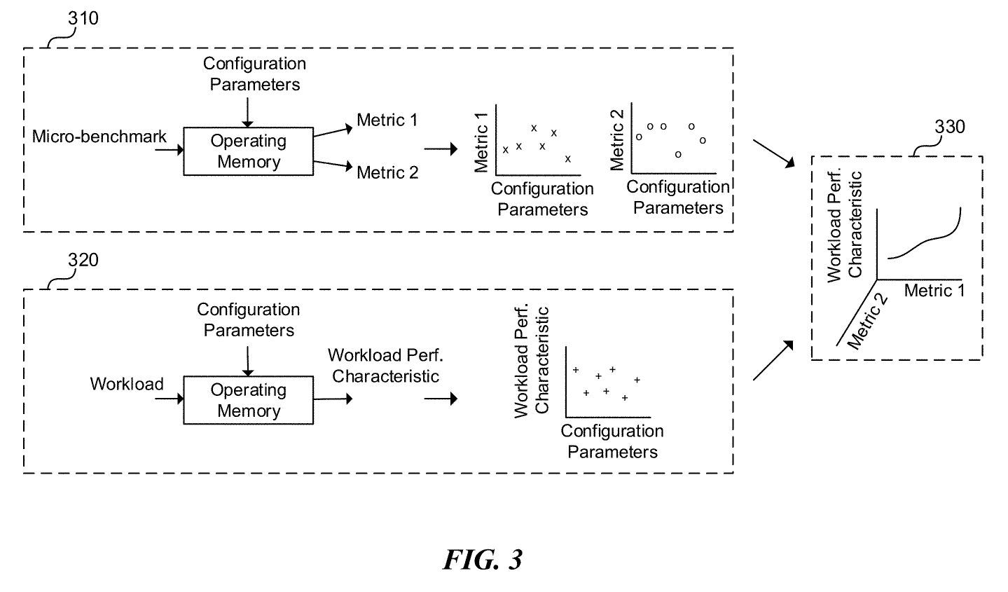

FIG. 3 illustrates an overview of an example embodiment of the disclosed technology. More specifically, FIG. 3 provides a logical illustration of an embodiment of the technology in which multiple memory performance metrics (e.g., latency, bandwidth, energy consumption) are evaluated for multiple sets of configuration parameters for the operating memory. In other words, FIG. 3 illustrates technology for finding a workload-specific memory configuration that improves workload performance.

As shown by 310, the operating memory is configured with configuration parameters and tested with micro-benchmarks to measure the impact of various access patterns on memory performance metrics, for example, latency (e.g., read, write, or both), bandwidth (e.g., read, write, or both), energy consumption, or the like. In the illustrated two-metric embodiment of FIG. 3, the metrics may be, for example, memory latency and memory bandwidth.

The configuration and testing of 310 may be performed using any number of computing devices. However, in at least one example, this configuration and testing is performed using multiple computing devices populated with operating memory modules without regard to inherent variation in their configuration, manufacturing process, or the like. Using multiple computing devices, a set of micro-benchmarks may be executed to measure loaded and unloaded latency and bandwidth for the operating memory. For example, this configuration and testing may be performed in BIOS, e.g., during a power-on self-test (POST) routine. In one example, this testing is performed by an automated tool as a POST routine. The operating memory may also be reconfigured and retested using multiple sets of configuration parameters.

The testing of the operating memory modules may also include negotiation of timing, frequency, and other settings, e.g., to determine a baseline set of configuration parameters for the operating memory. One or more computing devices can then be configured with the baseline set of configuration parameters, and testing may be performed to quantify the performance of the operating memory with respect to one or more of the metrics. Additional sets of configuration parameters, e.g., changing one or more of the configuration parameters for the operating memory, may also be tested to quantify the performance of the operating memory. The configuration parameters may be within the specifications for the operating memory devices, or outside of such specifications.

As shown by 320, the performance of a workload (e.g., the speed with which the workload executes, the energy consumed in executing the workload, the number of records processed by the workload, etc.) is analyzed with respect to different memory configuration parameters.

For example, testing, including executing different applications or other workloads using different sets of operating memory configuration parameters may be performed to measure performance characteristics for such workloads. For example, end-to-end performance for the workloads or energy consumption may be measured. This characterization approach enables development of models for the workload's sensitivity to operating memory metrics such as throughput and latency.

Further, test results may be saved, exported, or otherwise communicated, to another computing device. For example, the test data may be exported to another computing device, such as a data center load balancer. Such exporting may be performed prior to fully booting the computing device, e.g., by a routine of a network enabled BIOS, by a UEFI routine, by a network controller, or the like. Alternately, the test data may be saved and exported once the computing device has booted. Further, any suitable protocol may be employed to communicate the test data to the other computing device, or from a firmware routine to an operating system of the computing device. For example, the test data may be communicated via Simple Network Management Protocol (SNMP), Intelligent Platform Management Interface (IPMI), Advanced Configuration and Power Interface (ACPI), etc.

The exported data may be merged with data from other computing devices, or the data may be used by the other computing device to identify the computing devices that contain faster operating memory and re-allocate workloads that are sensitive to operating memory performance to those computing devices.

At 330, memory performance metrics from 310 and application performance data from 320 are employed together to characterize workload performance relative to the memory performance metrics. The use of these memory performance metrics and application performance data allows independent assessment of the impact of different memory performance metrics on workload performance. Potentially, this dependence can also be represented as a continuous function (shown at 330).

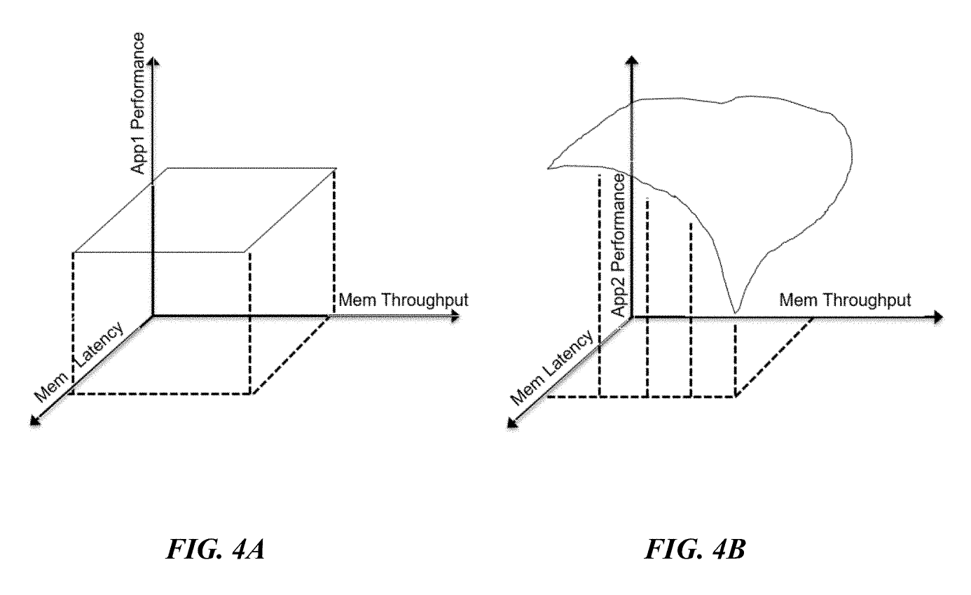

FIGS. 4A and 4B illustrate performance to configuration relationships according to an example embodiment of the disclosed technology. For example, the graphs of FIGS. 4A and 4B may be generated using the technology of FIG. 3. As illustrated in FIG. 4A, “App1” is insensitive to the performance of operating memory. However, “App2” as illustrated in FIG. 4B is more sensitive to the performance of operating memory. Accordingly, a load balancer may opt to assign App1 to computing devices with lower performance operating memory devices, and a system operator may elect to assign App2 to computing devices with higher performing operating memory devices, or purchase higher performing operating memory devices for computing devices to accommodate App2.

### Illustrative Processes

For clarity, the processes described herein are described in terms of operations performed in particular sequences by particular devices or components of a system. However, it is noted that other processes are not limited to the stated sequences, devices, or components. For example, certain acts may be performed in different sequences, in parallel, omitted, or may be supplemented by additional acts or features, whether or not such sequences, parallelisms, acts, or features are described herein. Likewise, any of the technology described in this disclosure may be incorporated into the described processes or other processes, whether or not that technology is specifically described in conjunction with a process. The disclosed processes may also be performed on or by other devices, components, or systems, whether or not such devices, components, or systems are described herein. These processes may also be embodied in a variety of ways. For example, they may be embodied on an article of manufacture, e.g., as computer-readable instructions stored in a computer-readable storage medium or be performed as a computer-implemented process. As an alternate example, these processes may be encoded as computer-executable instructions and transmitted via a communications medium.

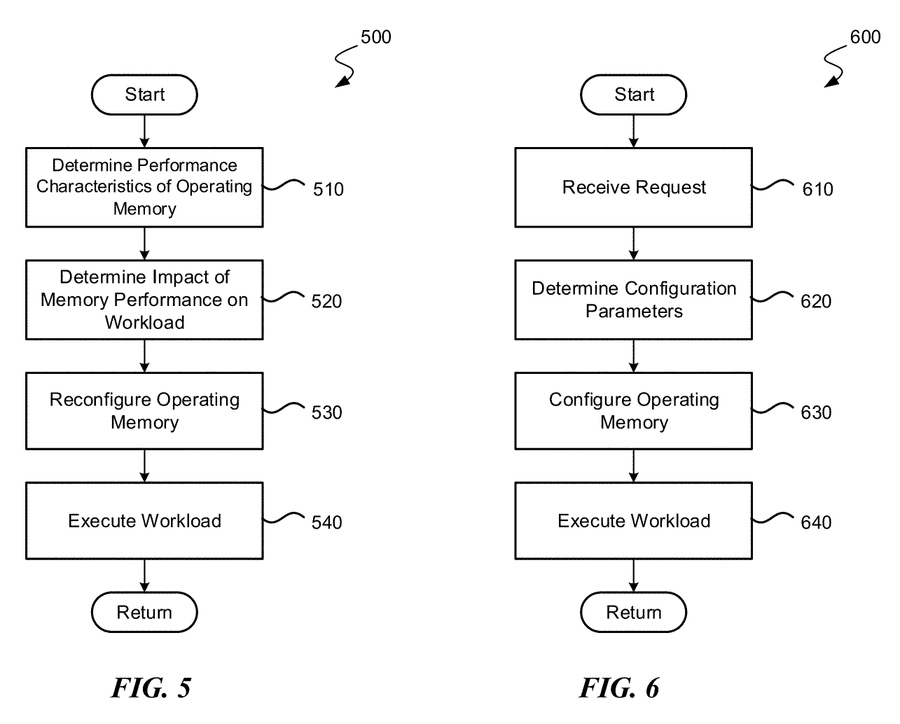

FIG. 5 is a logical flow diagram illustrating process 500 for improving execution performance for a workload. Process 500 begins at 510 where performance characteristics for an operating memory are determined. As one example, this includes determining the multiple performance characteristics/metrics for each of multiple sets of configuration parameters. This determining may also include testing operation of the operating memory using various configuration parameters, both within and outside of the operating memory's manufacturer's specifications. The processing of 510 may also include determining that some configuration parameters or sets of configuration parameters are unsuitable for the operating memory, e.g., due to reliability issues.

From 510, processing flows to 520 where an impact of the performance characteristics of the operating memory on workload are determined. For example, this may include determining an association between performance of a workload to be executed on the computing device and performance characteristics of the operating memory. Also, this may include testing execution of the workload using various sets of configuration parameters for the operating memory, such as discussed above in conjunction with FIG. 3.

From 520, processing flows to 530 where the configuration parameters for operating memory is reconfigured. This reconfiguration may be based on the determined performance configuration of the operating memory, on the determined impact of the configuration parameters on the application, or both.

From 530, processing flows to 540 where the workload is executed on the computing device, e.g., using the reconfigured operating memory. In at least one example, the execution of the workload is in response to an automatic assignment of the workload to the computing device based on determined performance characteristics of the operating memory in that computing device.

FIG. 6 is a logical flow diagram illustrating process 600 for executing workloads in a distributed computing system. Process 600 begins at 610 where a computing device receives a request to execute a workload. As one example, the request may be received in response to an automatic assignment of the workload to the computing device by another computing device, such as a datacenter's load balancer. The request may also be based on hardware testing of that computing device's operating memory.

From 610, processing flows to 620 where configuration parameters for the operating memory of the computing device are determined. Such determination may be by BIOS, or be based on information from BIOS. Further, the determination may be based at least in part on performance characteristics for the workload, e.g., based on a determination of the operating memory configuration parameters that provide suitable performance for that workload. The determination may also be based on information received from another computing device, e.g., a workload controller or load balancer, or based on information local to the computing device.

From 620, processing flows to 630 where the computing device is configured to operate according to the determined configuration parameters. For example, this configuring of the computing device may be performed, at least in part, by the BIOS of the computing device, the computing device.

From 630, processing flows to 640 where the workload is executed on the computing device. Execution of the workload may include the use of the operating memory of the computing device. For example, execution of the workload may include reading from the operating memory of the computing device according to the determined configuration parameters or writing to the operating memory of the computing device according to the determined configuration parameters.

### CONCLUSION

While the above Detailed Description describes certain embodiments of the technology, and describes the best mode contemplated, no matter how detailed the above appears in text, the technology can be practiced in many ways. Details may vary in implementation, while still being encompassed by the technology described herein. As noted above, particular terminology used when describing certain features or aspects of the technology should not be taken to imply that the terminology is being redefined herein to be restricted to any specific characteristics, features, or aspects with which that terminology is associated. In general, the terms used in the following claims should not be construed to limit the technology to the specific embodiments disclosed herein, unless the Detailed Description explicitly defines such terms. Accordingly, the actual scope of the technology encompasses not only the disclosed embodiments, but also all equivalent ways of practicing or implementing the technology.

We claim:

1. A method for improving performance of a computing device, the method comprising:
determining, via a firmware of the computing device and for an at least one operating memory device of the computing device, a plurality of performance characteristic sets, each of the plurality of performance characteristic sets having a corresponding configuration parameter set from a plurality of configuration parameter sets, each performance characteristic set of the plurality of performance characteristic sets associated with multiple performance characteristics for the at least one operating memory device, and each configuration parameter set of the plurality of configuration parameter sets defining multiple configurations parameters usable together for the at least one operating memory device;
in response to a request for a computing device to execute an application, selecting a configuration parameter set of the plurality of configuration parameter sets for the at least one operating memory device of the computing device, the selecting based at least in part on performance characteristics for the application and further based at least in part on the performance characteristic set corresponding to the selected configuration parameter set;
configuring, via the firmware, the computing device to operate the at least one operating memory device according to the selected configuration parameter set; and
executing the application on the computing device, the application execution comprising at least one use of the configured at least one operating memory device selected from the group consisting of reading from the at least one operating memory device according to the selected configuration parameter set, and writing to the at least one operating memory device of the computing device,
the determined plurality of performance characteristic sets determined based on a testing of the at least one operating memory device according to multiple configuration parameter sets,
the testing of the at least one operating memory device comprising determining that at least one of the multiple configuration parameter sets is unsuitable for the at least one operating memory device, and
the selected configuration parameter set includes configuration parameter selected from the group consisting of a clock frequency for the at least one operating memory device, and a clock cycle by clock cycle input/output specification for the at least one operating memory device.

2. The method of claim 1, further comprising:
testing operation of at least one operating memory device according to multiple configuration parameter sets, wherein the selected configuration parameter set is also determined based on the testing of at least one operating memory device.

3. The method of claim 2, further comprising:
in response to the testing, determining that at least one of the multiple configuration parameter sets is unsuitable for use with the at least one operating memory device.

4. The method of claim 1, wherein the request for the computing device to execute the application was in response to a selection of the application for execution on the computing device based at least in part on testing of operation of the at least one operating memory device in the computing device.

5. The method of claim 1, wherein the performance characteristics for the application are based on performance testing of the application using each of the plurality of configuration parameter sets.

6. The method of claim 1, wherein the request for the computing device to execute the application is a request for the computing device to execute the application on behalf of a distributed computing system.

7. A method for high performance computing, the method comprising:
determining performance characteristics of an operating memory in a computing device for each of multiple sets of configuration parameters, the individual sets of configuration parameters defining multiple configurations parameters usable together for employing the operating memory;
determining an impact of the performance characteristics of the operating memory on an application to be executed on the computing device;
reconfiguring the configuration parameters for the operating memory in the computing device based on both the determined performance configuration of the operating memory and on the determined impact of the configuration parameters on the application; and
executing the application on the computing device, the executing of the application including employing the operating memory.

8. The method of claim 7, further comprising:
automatically assigning the application to the computing device based at least in part on the determined performance characteristics of the operating memory.

9. The method of claim 7, wherein determining the performance characteristics of the operating memory includes:
determining at least one of a memory latency or a memory bandwidth for at least one of the multiple sets of configuration parameters, and wherein the method further comprises:
determining that at least one other set of configuration parameters is unsuitable for use with the computing device.

10. The method of claim 7, wherein determining the impact of the configuration parameters on the application includes:
determining an association between performance of the application and performance characteristics of the operating memory.

11. The method of claim 7, wherein the configuration parameters includes a clock cycle by clock cycle pipeline organization for the operating memory.

12. The method of claim 7, wherein at least one configuration parameter of at least one of the multiple sets of operating parameters is outside of a manufacturer specification for the operating memory.

13. The method of claim 7, wherein employing the operating memory includes:
reading from the operating memory according to the reconfigured configuration parameters; and
writing to the operating memory according to the reconfigured configuration parameters.

14. The method of claim 7, wherein the configuration parameters include a clock frequency for the operating memory.

15. A computing device, comprising:
an operating memory adapted to store run-time data for the computing device; and
at least one storage memory and at least one processor that are respectively adapted to store and execute instructions for causing the computing device to:
receive a request for the computing device to handle a workload as part of a distributed computing system;
in response to the received request, determine a set of configuration settings for the operating memory based at least in part on the workload, the set of configuration settings defining multiple configurations settings usable together to operate the operating memory device;
configure the computing device to operate the operating memory according to the determined set of configuration settings; and
handle the workload as part of the distributed computing system, the handling of the workload including storage of run-time data in the operating memory.

16. The computing device of claim 15, wherein the set of configuration settings is also determined based on performance testing of the workload on the computing device using each of multiple sets of configuration settings for the operating memory.

17. The computing device of claim 16, wherein the set of configuration settings is also determined based on a determined impact of the configuration settings on performance characteristics for the operating memory.

18. The computing device of claim 15, wherein the request is received in response to an automatic assignment of the workload to the computing device by another computing device based on hardware testing of the computing device.

19. The computing device of claim 15, wherein the determination of the set of configuration settings for the operating memory includes:
determining at least one of a memory latency or a memory bandwidth associated with at least one of the configuration settings; and
determining that at least one of the configuration setting is unsuitable for use with the computing device.

20. The computing device of claim 15, wherein the handling of the workload also includes:
reading from the operating memory device using the determined set of configuration parameters; and
writing to the operating memory device using the determined set of configuration parameters.
